(19) United States
(12) Patent Application Publication
(10) Pub. No.: US 2023/0175115 A1
(43) Pub. Date: Jun. 8, 2023

(54) SELECTIVE FILM FORMATION METHOD

(71) Applicants: TOKYO ELECTRON LIMITED, Tokyo (JP); TOHOKU UNIVERSITY, Miyagi (JP)

(72) Inventors: Shuji AZUMO, Nirasaki City, Yamanashi (JP); Kota UMEZAWA, Niraski City, Yamanashi (JP); Katsutoshi ISHII, Nirasaki City, Yamanashi (JP); Akira SHIMIZU, Nirasaki City, Yamanashi (JP); Akinobu TERAMOTO, Miyagi (JP); Tomoyuki SUWA, Miyashi (JP); Yasuyuki SHIRAI, Miyagi (JP); Takezo MAWAKI, Miyagi (JP)

(21) Appl. No.: 17/922,255

(22) PCT Filed: Mar. 29, 2021
(86) PCT No.: PCT/JP2021/013295

§ 371 Date: Oct. 28, 2022

(30) Foreign Application Priority Data
Apr. 30, 2020 (JP) 2020-080178

(51) Int. Cl. C23C 16/02; H01L 21/02; H01L 21/285; C23C 16/34; C23C 16/40; C23C 16/36; C23C 16/18; C23C 16/455

(52) U.S. Cl. CPC C23C 16/02; H01L 21/0206; H01L 21/02312; H01L 21/02205; H01L 21/02178; H01L 21/02186; H01L 21/02181; H01L 21/02164; H01L 21/02219; H01L 21/28568; C23C 16/34; C23C 16/401; C23C 16/36; C23C 16/345; C23C 16/403; C23C 16/405; C23C 16/18; C23C 16/45553; H01L 21/02271; H01L 21/0228

(57) ABSTRACT

A selective film forming method includes: preparing a substrate including a first film having a first surface and a second film having a second surface, the second film being different from the first film; selectively adsorbing a secondary alcohol gas and/or a tertiary alcohol gas to the second surface; and selectively forming a film on the first surface by supplying at least a raw material gas.

### TECHNICAL FIELD

The present disclosure relates to a selective film forming method.

### BACKGROUND

In a process of manufacturing a semiconductor device, a pattern is generally formed by photolithography and etching. However, in recent years, accuracy of the photolithography has reached the limit as miniaturization of semiconductor devices continues.

Therefore, there is a demand fix a technique of selectively forming a desired film in a self-aligned manner on a surface where a metal film such as wiring and an insulating film are mixed, for example, on the metal film.

Patent Document 1 proposes a method of selectively forming a thin film on a processing target substrate having a surface from which a conductive film and an insulating film are exposed, wherein a first surface as an exposed surface of the conductive film is made of Ru, RuO₂, Pt, Pd, CuO, and CuO₂, and an Ru film is selectively formed only on the first surface by using RutEtCp)₂ gas and O₂ gas.

### PRIOR ART DOCUMENTS

### Patent Documents

Patent Document 1: Japanese laid-open publication No. 2019-62142

### SUMMARY

The present disclosure provides a selective film forming method that is simple and highly versatile.

A selective film forming method according to a first aspect of the present disclosure includes: preparing a substrate including a first film having a first surface and a second film having a second surface, the second film being different from the first film; selectively adsorbing a secondary alcohol gas and/or a tertiary alcohol gas to the second surface; and selectively forming a film on the first surface by supplying at least a raw material gas.

A selective film forming method according to a second aspect of the present disclosure includes: preparing a substrate having a metal film and an insulating film, a natural oxide film being formed on a surface of the metal film: reducing and removing the natural oxide film to expose a first surface of the metal film; selectively adsorbing a secondary alcohol gas and/or a tertiany alcohol gas to a second surface of the insulating film; and selectively forming a film on the first surface by supplying at least a raw material gas.

According to the present disclosure, there is provided a selective film forming method that is simple and highly versatile.

### BRIEF DESCRIPTION OF DRAWINGS

FIG. 1 is a flowchart showing a selective film forming method according to a first embodiment.

FIG. 2A is a process cross-sectional view showing Step 1 of FIG. 1.

FIG. 2B is a process cross-sectional view showing Step 2 of FIG. 1.

FIG. 2C is a process cross-sectional view showing Step 3 of FIG. 1.

FIG. 3 is a flowchart showing a selective film forming method according to a second mbodiment.

FIG. 4A is a process cross-sectional view showing Step 11 of FIG. 3.

FIG. 4B is a process cross-sectional view showing Step 12 of FIG. 3.

FIG. 4C is a process cross-sectional view showing Step 13 of FIG. 3.

FIG. 4D is a process cross-sectional view showing Step 14 of FIG. 3.

FIG. 5 is a diagram showing decomposition characteristics of ethanol.

FIG. 6 is a diagram showing decomposition characteristics of 1-propanol.

FIG. 7 is a diagram showing decomposition characteristics of IPA.

FIG. 8 is a diagram showing decomposition characteristics of 1-butanol.

### DETAILED DESCRIPTION

Hereinafter, embodiments of the present disclosure will be described with reference to the accompanying drawings.

### First Embodiment

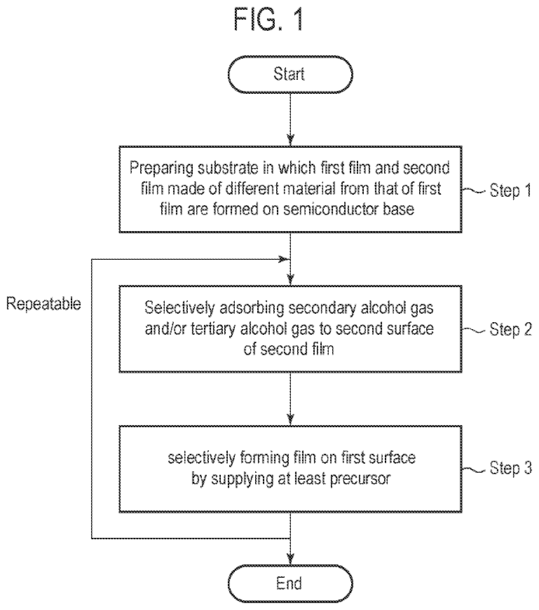

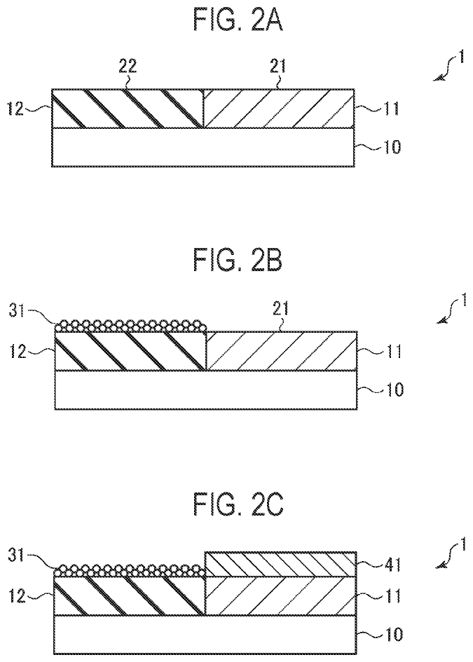

FIG. 1 is a flowchart showing a selective film forming method according to a first embodiment, and FIGS. 2A to 2C are process cross-sectional views showing each step shown in FIG. 1.

First, as shown in FIG. 2A, a substrate in which a first film 11 and a second film 12 made of a material different from that of the first film 11 are formed on a semiconductor base (e.g., Si) 10 is prepared (Step 1). The first film 11 has a first surface 21, and the second film 12 has a second surface 22. Specifically, in Step 1, the substrate 1 is mounted on a stage provided in a processing chamber.

The first film 11 may be a metal film, and any of Cu, Ru, Co, Ti, and TiN, or a combination thereof (at least one of Cu, Ru, Co, Ti, and TiN) may be an appropriate example. Further, the second film 12 may be an insulating film, and any of SiOₓ, SiOC, SiOCN, and SiN, or a combination thereof (at least one of SiOₓ, SiOC, SiOCN, and SiN) may be an appropriate example.

Next, a secondary alcohol gas and/or a tertiary alcohol gas is selectively adsorbed to the second surface 22 of the second film 12 (Step 2, FIG. 2B). Step 2 is performed by introducing the secondary alcohol gas and/or the tertiary alcohol gas into the chamber in which the substrate 1 is accommodated. An organic layer 31 formed by the adsorption only needs to be adsorbed to an entirety of the second surface 22, but does not need to be a film. The organic layer 31 functions as a blocking member that blocks film formation on the second surface 22 during next film formation.

The secondary alcohol is an alcohol in which a carbon atom having a hydroxyl group (—OH group) attached thereto bonds to two other carbon atoms, and the tertiary alcohol is an alcohol in which a carbon atom having a hydroxyl group attached thereto bonds to three other carbon atoms.

Examples of the secondary alcohol may include isopropyl alcohol (IPA) and 2-butanol. Further, examples of the tertiary alcohol may include tertiary butyl alcohol (2-methyl propanol) and 2-methyl-2-butanol. Note that these are only examples, and the present disclosure is not limited to the examples described above.

Compared to a normal type alcohol (a primary alcohol, i.e., an alcohol in which a hydroxyl group is attached to a terminal carbon atom) such as ethanol, 1-propanol, and 1-butanol, the secondary alcohol and the tertiary alcohol have a lower dehydrogenation initiation temperature, and thus, an adsorption temperature thereof may be lowered by about 50 degrees C. In particular, IPA gas highly tends to do so. This is because dehydrogenation of the primary alcohol produces aldehyde, whereas dehydrogenation of the secondary alcohol and the tertiary alcohol produces ketone. That is, since aldehyde (acetaldehyde, propanal, or the like) is produced at a relatively high temperature, whereas ketone (acetone, methyl ethyl ketone, or the like) is produced at a temperature lower than aldehyde, the secondary alcohol and the tertiary alcohol undergo a dehydrogenation reaction at a lower temperature, thus being adsorbed.

The adsorption of the secondary alcohol gas and/or the tertiary alcohol gas in Step 2 may be carried out within a temperature range of 100 degrees C. to 350 degrees C., more specifically, within a temperature range of 100 degrees C. to 250 degrees C. According to the alcohol used, the adsorption may be carried out fn a temperature range of 100 degrees C. to 150 degrees C.

In particular, the temperature range of 100 degrees C. to 150 degrees C. is appropriate when IPA gas is used, A time period of Step 2 is desirably set to a time period sufficient to allow the organic layer 31 to be adsorbed to the entirety of the second surface 22. The secondary alcohol gas and the tertiary alcohol gas are relatively easy to be adsorbed, and may be adsorbed within a relatively short time period of 1 second to 60 seconds.

An alcohol gas has a property of being easily adsorbed to a surface of an insulating film, but difficult to be adsorbed to a surface of a metal film such as Cu. Therefore, when the first film 11 is a metal film and the second film 12 is an insulating film, the alcohol gas may be selectively adsorbed to the second surface 22. In the present embodiment, since the secondary alcohol gas and/or the tertiary alcohol gas is used as the alcohol gas, the organic layer 31 may be formed by selectively adsorbing the alcohol gas to the second surface 22 within the relatively low temperature range as described above.

When the metal film is Cu, it is desirable that a temperature of a process after the metal film is formed be low because Cu is very sensitive to temperature and very easily migrates. In particular, since the metal film, i.e., Cu is in an exposed state when performing the adsorption process of Step 2, the temperature is particularly required to be lowered. On the other hand, in the present embodiment, the temperature of Step 2 may be lowered by using the secondary alcohol gas and/or the tertiary alcohol gas as the adsorption gas of Step 2, which may prevent adverse effects such as migration of Cu, for example. In addition, when the temperature of a subsequent film forming process of Step 3, which will be described below, can be lowered, the migration of the metal film may be more effectively prevented, and thus, it is anticipated to further enhance the selectivity of film formation. When the adsorption process of Step 2 is performed at a high temperature, in addition to the adverse effect on the metal film as described above, it is necessary to change a temperature of the chamber or to use a separate chamber when the next film formation is performed at a low temperature, which results in deterioration in productivity,

Next, at least a raw material gas (precursor) is supplied to selectively form a film 41 on the first surface 21 (Step 3, FIG. 2C). The selective in film formation of Step 3 is implemented by the blocking function of the organic layer 31. The film formation at this time may be performed either by a reaction of the raw material gas (precursor) and a reactive gas (reactant), or may be performed by thermal decomposition of the raw material gas (precursor).

When forming a film by a reaction of the precursor and the reactant, the film may be formed by atomic layer deposition (ALD) or chemical vapor deposition (CVD). Between these, ALD in which the precursor and the reactant are alternately adsorbed to form a film by a surface reaction is more desirable. In the case of ALD, the organic layer 31 inhibits adsorption of the precursor to the second surface 22 to block the surface reaction. Therefore, the selectivity in film formation of the film 41 may be maintained at a high level. A temperature at this time is desirably 450 degrees C. or less.

When forming a film by a decomposition reaction of the precursor, the film may be formed by CVD. Examples of forming a film by the decomposition reaction of the precursor may include forming a Co film by using cobalt carbonyl (Co₂(CO)₈) as the raw material gas and forming a Ru film by using ruthenium carbonyl (Ru₃(CO)₁₂) as the raw material gas.

The film 41 is not particularly limited and may be a metal film or an insulating film. Further, a combination of the precursor and the reactant is not particularly limited as long as the blocking function of the organic layer 31 may be maintained for a required time period during film formation.

When the film 41 is a metal film, any of Ru, Cu, Co, Ti, and TiN, or a combination thereof (at least one of Ru, Cu, Co, Ti, and TiN) may be an appropriate example. Further, when the film 41 is an insulating film, any of SiOₓ, SiOC, SiOCN, SiN, AlₓO_{y}, HfOₓ, ZrOₓ, TiOₓ, TiON, or a combination thereof (at least one of SiOx, SiOC, SiOCN, SiN, AlₓO_{y}, HfOₓ, ZrOₓ, TiOₓ, and TiON) may be an appropriate example.

As the precursor for film formation, various ones may be used according to a film to be formed. The precursor may be an organic compound or an inorganic compound, but an organic compound is more desirable. Further, the reactant for film formation may be selected according to a film to be formed, but H₂O and H₂ may be used appropriately from the viewpoint of exhibiting the blocking function of the organic layer 31. An oxide film will be formed as the film 41 when using H₂O as the reactant, and a metal film will be formed as the film 41 when using H₂ as the reactant. When H₂O or H₂ is used as the reactant, the film forming temperature is desirably 450 degrees C. or less, and more specifically 350 degrees C. Further, O₂ is also desirable as the reactant, and an oxide film or a metal film will be formed when using O₂ as the reactant. When O₂ is used as the reactant, the film forming temperature is desirably 300 degrees C. or less, and more specifically 250 degrees C. or less. Of course, a nitride film may be formed by using a nitriding agent such as NH₃ as the reactant, or other films may be formed by using other reactants.

Appropriate examples of the material of the film 41, the precursor, the reactant, and the film forming temperature are exemplified as follows.
(1) Material of Film 41: Ru
   Precursor: Ru(EtCp)₂
   Reactant: O₂
   Temperature: 300 degrees C. or less
(2) Material of Film 41: AlO
   Precursor: trimethylaluminum (TMA)
   Reactant H₂O
   Temperature: 450 degrees C or less
(3) Material of Film 41: CO
   Precursor: CO₂(CO)₈
   Reactant: None
   Temperature: 300 degrees C. or less
(4) Material of Film 41: TiOₓ
   Precursor: Ti(NMe₂)₄
   Reactant H₂O
   Temperature: 50 degrees C. to 250 degrees C.
(5) Material of Film 41: HfOₓ
   Precursor: Hf(NMe₂)₄
   Reactant H₂O
   Temperature: 50 degrees C. to 400 degrees C.
(6) Material of Film 41: SiOₓ
   Precursor: SiH(NMe₂)₄
   Reactant H₂O
   Temperature: 400 degrees C.

Steps 2 and 3 described above are desirably performed under a vacuum atmosphere, and for example, may be performed within a range of 13 Pa to 1333 Pa. Further, Steps 2 and 3 may be performed consecutively in the same chamber. When Steps 2 and 3 are performed in the same chamber, it is desirable to perform both the steps at the same temperature.

Steps 2 and 3 described above may be alternately repeated two or more times. When forming the film 41. the organic layer 31 may be eroded during the film formation according to the type of the reactant in Step 3. However, by repeating Steps 2 and 3, the blocking function of the organic layer 31 may be maintained until the film 41 reaches a desired film thickness, thereby achieving selective film formation,

The selective film forming technique disclosed in Patent Document 1 is mainly focused on forming a conductive film on a conductive film and forming an insulating film on an insulating film, and thus materials of an underlying film and a film formed thereon, precursors, and reactants for selective film formation are limited. In contrast, in the present embodiment, with a simple method of selectively adsorbing a general organic compound including the secondary alcohol gas such as IPA or the tertiary alcohol gas to cause the adsorbed organic compound to function as a blocking material that blocks film formation, it is possible to implement selective film formation with few restrictions and high versality. Further, since the secondary alcohol gas such as IPA or the tertiary alcohol gas may have a lower adsorption temperature, it is advantageous when a metal film such as Cu exists. Further, since the secondary alcohol gas such as IPA and the tertiary alcohol gas are easy to handle and have relatively high adsorptivity, they require less labor and a short processing time. Further, there is also an advantage that an applicable temperature range thereof is wide.

### Second Embodiment

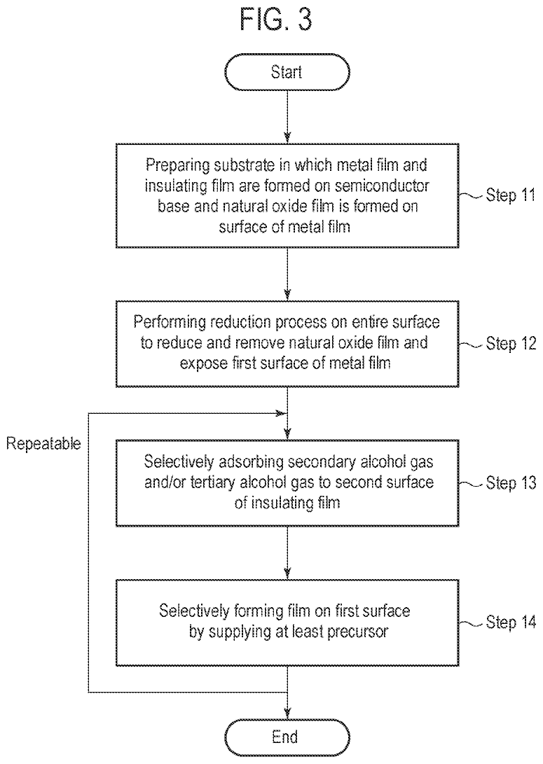

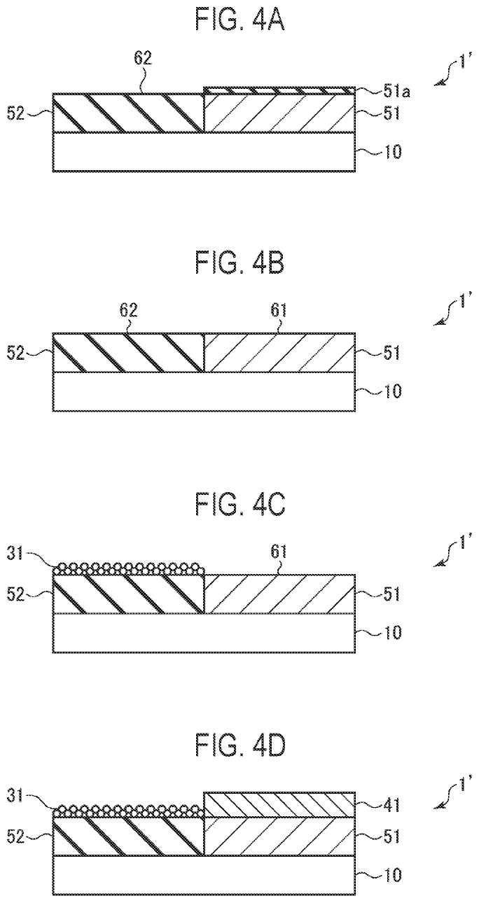

FIG. 3 is a flowchart showing a selective film forming method according to a second embodiment, and FIGS. 4A to 4D are process cross-sectional views showing each step shown in FIG. 3.

When a metal is held in the atmosphere, a natural oxide film is inevitably formed on a surface of the metal. Thus, in the present embodiment, selective film formation on a substrate having a natural oxide film will be described.

First, as shown in FIG. 4A, a substrate 1′ in which a metal film 51 and an insulating film 52 are formed on a semiconductor base (e.g., Si) 10 and a natural oxide film 51a is formed on a surface of the metal film 51 is prepared (Step 11). The insulating film 52 has a second surface 62, Specifically, in Step II, the substrate 1′ is mounted on a stage provided in a processing chamber.

Any of Cu, Ru, Co, Ti, and TiN, or a combination thereof (at least one of Ru, Cu, CoTi, and TiN) may be an appropriate example of the metal film 51. Further, any of SiOₓ, SiOC, SiOCN, and SiN, or a combination thereof (at least one of SiOₓ, SiOC, SiOCN, and SiN) may be an appropriate example of the insulating film 52. The natural oxide film 51a is an oxide film formed on the surface of the metal film 51, and at least one oxide film of Cu, Ru, Co, and Ti may be an appropriate example.

Next, an entire surface is subjected to a reduction process as a pretreatment to reduce and remove the natural oxide film 51a and expose a first surface 61 of the metal film 51 (Step 12, FIG, 4B). At this time, the second surface 62 of the insulating film 52 remains as it is, and only the natural oxide film 51a is removed. The reason for removing the natural oxide film 51a is because an organic compound containing an —OH group is easily adsorbed to a metal oxide film and it is difficult to obtain selective adsorptivity on the metal oxide film.

Step 12 may be performed by a hydrogen annealing process or a hydrogen plasma process. A temperature at this time is desirably 500 degrees C. or less, and more specifically 400 degrees C. or less. In the hydrogen annealing process, the temperature is more desirably 250 degrees C. to 400 degrees C., and in the hydrogen plasma process, the temperature is more desirably lower than that in the hydrogen annealing process, for example, 400 degrees C. or less, In the case of the hydrogen annealing process, the substrate 1′ is annealed while hydrogen gas (H₂ gas) is introduced into the chamber in which the substrate 1′ is accommodated. The hydrogen plasma process is performed by causing hydrogen plasma to act on the substrate 1′ in the chamber. The reduction process in Step 12 may also be performed using an organic compound containing an —OH group. In this case, the reduction process may be performed simultaneously with a next adsorption process of Step 13. Note that the hydrogen annealing process and the hydrogen plasma process are desirable when the natural oxide film is formed thick.

Next, the secondary alcohol gas and/or the tertiary alcohol gas is selectively adsorbed to the second surface 62 of the insulating film 52 (Step 13, FIG. 4C). Step 13 may be performed in the same manner as Step 2 of the first embodiment. As in the first embodiment, the organic layer 31 formed by adsorption has selective adsorptivity and a blocking function, and is selectively adsorbed to the second surface 62 to block film formation on the second surface 62 during film formation, Also in the present embodiment, for example, isopropyl alcohol (IPA) and 2-butanol may be used as the secondary alcohol, and, for example, tertiary butyl alcohol (2-methyl-2-propanol) and 2-methyl-2-butanol may be used as the tertiary alcohol. The processing temperature is also the same as in Step 2 of the first embodiment.

Next, at least a raw material gas (precursor) is supplied to selectively form the film 41 on the first surface 61 (Step 14, FIG. 4D). The selectivity in film formation of Step 14 is implemented by the blocking function of the organic layer 31. The film formation at this time may be performed either by a reaction of the raw material gas (precursor) and a reactive gas (reactant), or may be performed by thermal decomposition of the raw material gas (precursor), as in Step 3 of the first embodiment. When forming a film by the reaction of the precursor and the reactant, it may be performed by ALD or CVD, but ALD is more desirable. When forming a film by a decomposition reaction of the precursor, it may be performed by CVD. The precursor, the reactant, and a combination thereof as well as the temperature, and the like when performing Step 14 are the same as in Step 3 of the first embodiment.

Steps 12 to 14 described above are desirably performed under a vacuum atmosphere, and for example, may be performed within the range of 13 Pa to 1333 Pa. Further, Steps 12 to 14 may be performed consecutively in the same chamber. When Steps 12 to 14 are performed in the same chamber, it is desirable to perform Steps 12 to 14 at the same temperature. Similar to Steps 2 and 3 of the first embodiment, Steps 13 and 14 may be alternately repeated two or more times.

Also in the present embodiment, as in the first embodiment, with a simple method of selectively adsorbing a general organic compound including the secondary alcohol gas such as IPA or the tertiary alcohol gas to cause it to function as a blocking material that blocks film formation, it is possible to implement selective film formation with few restrictions and high versatility. Further, since the secondary alcohol gas such as IPA or the tertiary alcohol gas may have a lower adsorption temperature, it is advantageous when a metal film such as Cu exists.

### <Experimental Example>

Next, an experimental example will be described.

Here, decomposition characteristics of ethanol, 1-propanol, IPA, and 1-butanol on a SiO pipe were investigated. After baking the SiO pipe with Ar gas at 450 degrees C. for two hours, the respective gases were supplied while increasing the temperature.

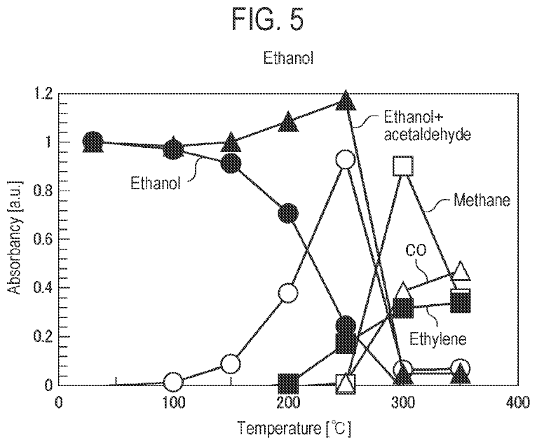

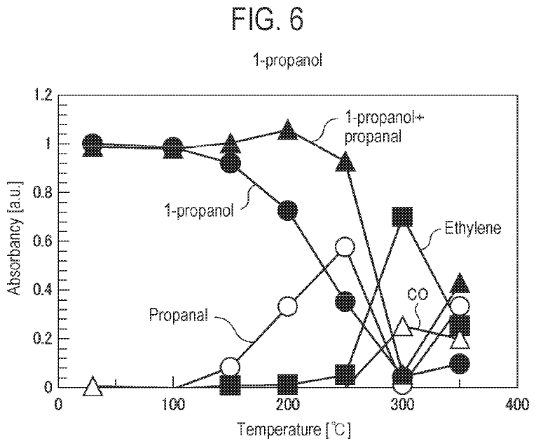

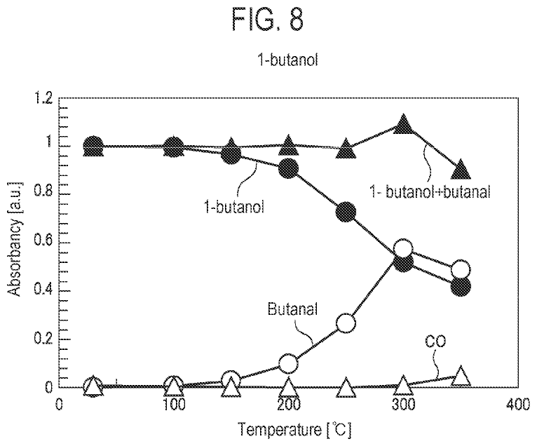

Analysis results by IR spectrum at that time are shown in FIGS. 5 to 8. In the case of ethanol, as shown in FIG. 5, it was confirmed that dehydrogenation started around 150 degrees C. to produce acetaldehyde, and an amount of acetaldehyde increased as the temperature increased. In the case of 1-propanol, as shown in FIG. 6, it was confirmed that dehydrogenation similarly started around 150 degrees C. to produce propanal, and an amount of propanal increased as the temperature increased. In the case of 1-butanol, as shown in FIG. 8, it was confirmed that dehydrogenation similarly started around 150 degrees C. to produce butanal, and an amount of butanol increased as the temperature increased. That is, in the case of ethanol, 1-propanol, and 1-butanol which are the normal type alcohol (primary alcohol), it was confirmed that starting temperatures of the dehydrogenation were all around 150 degrees C., and aldehyde was produced by dehydrogenation.

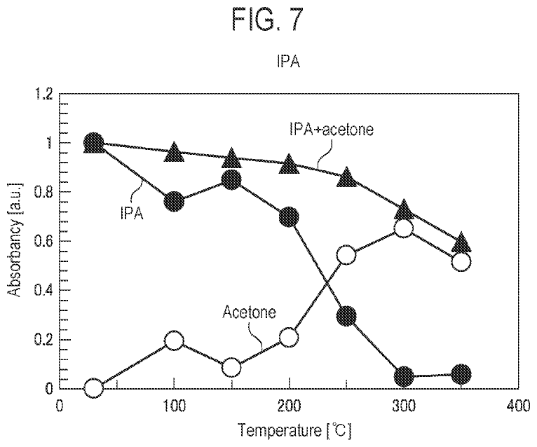

On the other hand, in the case of IPA which is the secondary alcohol, as shown in FIG. 7, it was confirmed that acetone, which is ketone, was produced by dehydrogenation, and a staring temperature of the dehydrogenation was about 100 degrees C., which is lower compared to other gases. That is, in the case of IPA, it was confirmed that IPA decomposes at a low temperature of 100 degrees C. to produce acetone, which is adsorbed to a surface to form an organic layer.

### <Other Applications>

Although the embodiments have been described above, the embodiments disclosed herein should be considered to be exemplary and not restrictive in all respects. The above embodiments may be omitted, replaced, or modified in various ways without departing from the scope and spirit of the appended claims.

For example, in the above embodiments, a substrate in which a first film (metal film) and a second film (insulating film) are formed on a base has been schematically illustrated (FIGS. 2A to 2C and FIGS. 4A to 4D) to describe a general example. However, the present disclosure is not limited thereto, and may be applied to various devices, and the first film and the second film may take ⁻various forms according to a device to which they are applied. Further, in the embodiments described above, the case of selectively forming a film on one of the surfaces of two films has been described, but the present disclosure is not limited thereto, and may also be applied to selective film formation with respect to three or more films.

### EXPLANATION OF REFERENCE NUMERALS

1, 1′: substrate, 10: base, 11: first film, 12: second film, 21, 61: first surface, 22, 62: second surface, 31: adsorbed layer, 41: film, 51: metal film, 52: insulating film

1. A selective film forming method comprising:
preparing a substrate including a first film having a first surface and a second film having a second surface, the second film being different from the first film;
selectively adsorbing at least one selected from the group of a secondary alcohol gas and a tertiary alcohol gas to the second surface; and
selectively forming a film on the first surface by supplying at least a raw material gas.

2. The selective film forming method of claim 1, wherein the first film is a metal film and the second film is an insulating film.

3. The selective film forming method of claim 2, wherein the metal film constituting the first film is at least one selected from the group consisting of Cu, Ru, Co, Ti, and TiN, and the insulating film constituting the second film is at least one selected from the group consisting of SiOₓ, SiOC, SiOCN, and SiN.

4. A selective film forming method comprising:
preparing a substrate including a metal film and an insulating film, a natural oxide film being formed on a surface of the metal film;
reducing and removing the natural oxide film to expose a first surface of the metal film;
selectively adsorbing at least one selected from the group of a secondary alcohol gas and a tertiary alcohol gas to a second surface of the insulating film; and
selectively forming a film on the first surface by supplying at least a raw material gas.

5. The selective film forming method of claim 4, wherein the reducing and removing the natural oxide film is performed by a hydrogen annealing process or a hydrogen plasma process.

6. The selective film forming method of claim 5, wherein the hydrogen annealing process or the hydrogen plasma process is performed at a temperature of 500 degrees C. or less.

7. The selective film forming method of claim 6, wherein the hydrogen annealing process is performed at a temperature of 250 degrees C. to 400 degrees C., and the hydrogen plasma process is performed at a temperature of 400 degrees C. or less.

8. The selective film forming method of claim 4, wherein the reducing and removing the natural oxide film is performed simultaneously with the selectively adsorbing at least one selected from the group of the secondary alcohol gas and the tertiary alcohol gas to the second surface.

9. The selective film forming method of claim 4, wherein the metal film is at least one selected from the group consisting of Cu, Ru, Co, Ti, and TiN, and the insulating film is at least one selected from the group consisting of SiOₓ, SiOC, SiOCN, and SiN.

10. The selective film forming method of claim 1, wherein an organic layer adsorbed by the selectively adsorbing at least one selected from the group of the secondary alcohol gas and the tertiary alcohol gas to the second surface has a function of blocking film formation on the second surface by at least the raw material gas.

11. The selective film forming method of claim 10, wherein the selectively adsorbing at least one selected from the group of the secondary alcohol gas and the tertiary alcohol gas to the second surface is performed at a temperature within a range of 100 degrees C. to 350 degrees C.

12. The selective film forming method of claim 11, wherein the selectively adsorbing at least one selected from the group of the secondary alcohol gas and the tertiary alcohol gas to the second surface is performed at a temperature within a range of 100 degrees C. to 250 degrees C.

13. The selective film forming method of claim 1, wherein the secondary alcohol gas is at least one selected from the group of isopropyl alcohol and 2-butanol.

14. The selective film forming method of claim 13, wherein the selectively adsorbing at least one selected from the group of the secondary alcohol gas and the tertiary alcohol gas to the second surface is performed at a temperature within a range of 100 degrees C. to 150 degrees C. when isopropyl alcohol is used as at least one selected from the group of the secondary alcohol gas and the tertiary alcohol gas.

15. The selective film forming method of claim 1, wherein the tertiary alcohol gas is at least one selected from the group of tertiary butyl alcohol and 2-methyl-2-butanol.

16. The selective film forming method of claim 1, wherein the selectively adsorbing at least one selected from the group of the secondary alcohol gas and the tertiary alcohol gas to the second surface and the selectively forming the film on the first surface are alternately repeated two or more times.

17. The selective film forming method of claim 1, wherein the film formed by the selectively forming the film on the first surface is a metal film or an insulating film.

18. The selective film forming method of claim 17, wherein the metal film on the first surface is at least one selected from the group consisting of Cu, Ru, Co, Ti, and TiN, and the insulating film on the first surface is at least one selected from the group consisting of SiOₓ, SiOC, SiOCN, SiN, AlₓO_{y}, HfOₓ, ZrOₓ, TiOₓ, and TiON.

19. The selective film forming method of claim 1, wherein the selectively forming the film on the first surface is performed by supplying the raw material gas and a reaction gas.

20. The selective film forming method of claim 19, wherein the selectively forming the film on the first surface is performed by atomic layer deposition (ALD) or chemical vapor deposition (CVD).

21. The selective film forming method of claim 19, wherein the selectively forming the film on the first surface is performed at a temperature of 450 degrees C. or less.

22. The selective film forming method of claim 19, wherein any one of H₂O, H₂, and O₂ is used as the reaction gas.

23. The selective film forming method of claim 22, wherein the selectively forming the film on the first surface includes forming a Ru film by using Ru(EtCp)₂ as the raw material gas and using O₂ as the reaction gas.

24. The selective film forming method of claim 22, wherein the selectively forming the film on the first surface includes forming an AlₓO_{y} film by using trimethylaluminum (TMA) as the raw material gas and using H₂O as the reaction gas.

25. The selective film forming method of claim 22, wherein the selectively forming the film on the first surface includes forming a TiOₓ film by using Ti(NMe₂)₄ as the raw material gas and using H₂O as the reaction gas.

26. The selective film forming method of claim 22, wherein the selectively forming the film on the first surface includes forming a HfOₓ film by using Hf(NMe₂)₄ as the raw material gas and using H₂O as the reaction gas.

27. The selective film forming method of claim 22, wherein the selectively forming the film on the first surface includes forming a SiOₓ film by using SiH(NMe₂)₄ as the raw material gas and using H₂O as the reaction gas.

28. The selective film forming method of claim 1, wherein the selectively forming the film on the first surface is performed by supplying and thermally decomposing the raw material gas.

29. The selective film forming method of claim 28, wherein the selectively forming the film on the first surface is performed by chemical vapor deposition (CVD).

30. The selective film forming method of claim 29, wherein the selectively forming the film on the first surface includes forming a Co film by using Co₂(CO)₈ as the raw material gas and thermally decomposing the raw material gas.
